(19) United States
(12) Patent Application Publication
(10) Pub. No.: US 2025/0081627 A1
(43) Pub. Date: Mar. 6, 2025

(54) ESD PROTECTION DEVICE OF AN INTEGRATED CIRCUIT

(71) Applicant: STMicroelectronics International N.V., Geneva (CH)

(72) Inventors: Chloe TROUSSIER, Grenoble (FR); Johan BOURGEAT, Crêts En Belledonne (FR)

(73) Assignee: STMicroelectronics International N.V., Geneva (CH)

(21) Appl. No.: 18/820,139

(22) Filed: Aug. 29, 2024

(30) Foreign Application Priority Data
Sep. 6, 2023 (FR) 2309348

(51) Int. Cl. H01L 27/02

(52) U.S. Cl. CPC H10D 89/814; H10D 89/611; H10D 89/911

(57) ABSTRACT

An ESD protection device includes at least one semiconductor electronic switch electrically coupled in parallel with a diode. The semiconductor electronic switch and the diode each include at least one finger extending substantially parallel to a first direction. The fingers of the semiconductor electronic switch and of the diode are aligned with each other along this first direction.

### CROSS-REFERENCE TO RELATED APPLICATION(S)

This application claims the priority benefit of French patent application number FR2309348, filed on Sep. 6, 2023, entitled “Dispositif de protection ESD pour circuit intégré,” which is hereby incorporated by reference to the maximum extent allowable by law.

### BACKGROUND

### Technical Field

The present disclosure generally concerns the field of ElectroStatic Discharge (ESD) protection, or protection against electrostatic discharges.

### Description of the Related Art

The inputs/outputs of integrated circuits include ESD protection circuits. For example, for the package of an integrated circuit, the ESD protection circuit at each of the pins of the package may be such that it withstands a 2-kV HBM (that is, according to the HBM model or Human Body Model) voltage electrostatic discharge. However, for the integrated circuit substrate, or wafer, the called—for ESD protection level for the inputs/outputs is generally lower, for example such that the inputs/outputs withstand a 200-V HBM voltage electrostatic discharge.

When pins of the integrated circuit package are electrically coupled to one another (as may for example be the case of pins intended to receive the integrated circuit power supply voltage), the ESD protection thresholds of the circuits of each of the inputs/outputs coupled to these pins add. To guarantee that this addition reaches the ESD protection level called for the pins of the package, the ESD protection circuits of the integrated circuit inputs/outputs may be sized so that each of them can withstand the electrostatic voltage discharge level called for the package pins. Although this solution guarantees an ESD protection level sufficient for the package pins (even for the integrated circuit inputs/outputs each coupled to a single pin of the package), this oversizing of the ESD protection circuits of the integrated circuit inputs/outputs results in a significant semiconductor occupied surface area for the forming of these protection circuits, uselessly increasing the total semiconductor surface area called for the integrated circuit.

Alternatively to the above solution, the ESD protection circuits of the integrated circuit inputs/outputs may be individually sized according to the wiring provided with the package pins. This alternative solution is however highly time consuming due to the specific design called for each of the ESD protection circuits of the integrated circuit inputs/outputs.

### BRIEF SUMMARY

Embodiments of the present disclosure provide ESD protection that overcomes at least some of the drawbacks of previous solutions.

In one embodiment, an ESD protection device includes at least one semiconductor electronic switch electrically coupled in parallel with a diode, wherein the semiconductor electronic switch and the diode each include at least one finger extending substantially parallel to a first direction, the fingers of the semiconductor electronic switch and of the diode being aligned with each other along this first direction.

According to a specific embodiment, the semiconductor electronic switch and the diode each include a plurality of fingers, each finger of the semiconductor electronic switch being aligned with one of the fingers of the diode along the first direction, forming together a pair of fingers, the pairs of fingers being aligned with one another along a second direction substantially perpendicular to the first direction.

According to a specific embodiment, the ESD protection device includes at least one resistor having its larger dimension substantially parallel to the first direction.

According to a specific embodiment, the semiconductor electronic switch includes a GGNMOS- or GCPMOS- or BiCMOS-type transistor, or includes a thyristor.

According to a specific embodiment, the ESD protection device further includes two connection terminals having electrodes of the semiconductor electronic switch and of the diode coupled thereto.

According to a specific embodiment, the semiconductor electronic switch and the diode, or each pair of fingers of the semiconductor electronic switch and of the diode when the semiconductor electronic switch and the diode each include a plurality of fingers, are configured to withstand an electrostatic discharge voltage having a value equal to a target ESD protection value for the substrate.

Another specific embodiment provides an integrated circuit including a plurality of inputs/outputs, each electrically coupled to at least one ESD protection device such as described hereabove.

According to a specific embodiment, the ESD protection devices form part of an input/output (I/O) circuit arranged at the periphery of a core region of the integrated circuit.

According to a specific embodiment, the integrated circuit further includes a package provided with a plurality of pins, each electrically coupled to at least one of the inputs/outputs, at least one group of pins being electrically coupled together, the ESD protection devices coupled to the group of pins or to each of the groups of pins being configured to withstand together an electrostatic discharge voltage having a value equal to a target ESD protection value for the package.

According to a specific embodiment, at least one of the pins of the package is electrically coupled to none of the other pins, the ESD protection device coupled to said at least one of the pins being configured to withstand alone an electrostatic discharge voltage having a value equal to the target ESD protection value for the package.

In one embodiment, an ESD protection device a diode including at least one first finger and at least one semiconductor electronic switch electrically coupled in parallel with the diode and including at least one second finger. The at least one first finger and the at least one second finger extend substantially parallel to a first direction and are aligned with each other along the first direction.

In one embodiment, an integrated circuit includes an ESD protection device including a plurality of diodes each including a first finger extending in a first direction and a plurality of switches each including a second finger extending in the first direction and aligned in the first direction with a respective first finger. The integrated circuit includes a plurality of input/output (I/O) terminals electrically coupled the ESD protection device.

In one embodiment, an integrated circuit includes an ESD protection device. The ESD protection device includes a plurality of pairs of fingers, each pair of fingers including a first finger and a second finger each extending in a first direction and aligned with each other along the first direction. The ESD protection device includes a plurality of diodes, each diode including a respective first finger and a plurality of switches, each switch including a respective second finger.

### BRIEF DESCRIPTION OF THE SEVERAL VIEWS OF THE DRAWINGS

The foregoing features and advantages, as well as others, will be described in detail in the rest of the disclosure of specific embodiments given by way of illustration and not limitation with reference to the accompanying drawings, in which:

FIG. 1 schematically shows an ESD protection device, in accordance with one embodiment;

FIG. 2 shows layout of an ESD protection device, in accordance with one embodiment;

FIG. 3 shows, in the form of a functional diagram, an ESD protection device, in accordance with one embodiment; and

FIG. 4 schematically shows an integrated circuit including ESD protection devices, in accordance with one embodiment.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for the understanding of the described embodiments have been illustrated and described in detail. In particular, different elements (transistor, thyristor, diode, etc.) of the ESD protection device, as well as the different portions of the integrated circuit (core, I/O circuit, package) are not described in detail. Those skilled in the art will be capable of making in detailed fashion these elements based on the functional description given herein.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “edge,” “back,” “top,” “bottom,” “left,” “right,” etc., or relative positions, such as terms “above,” “under,” “upper,” “lower,” etc., or to terms qualifying directions, such as terms “horizontal,” “vertical,” etc., it is referred, unless specified otherwise, to the orientation of the drawings in a normal position of use. Similarly, the terms “parallel” and “perpendicular” are interpreted by considering angle differences corresponding to the manufacturing tolerances normally admitted in the field.

Unless specified otherwise, the expressions “about,” “approximately,” “substantially,” and “in the order of” signify plus or minus 10%, preferably of plus or minus 5%.

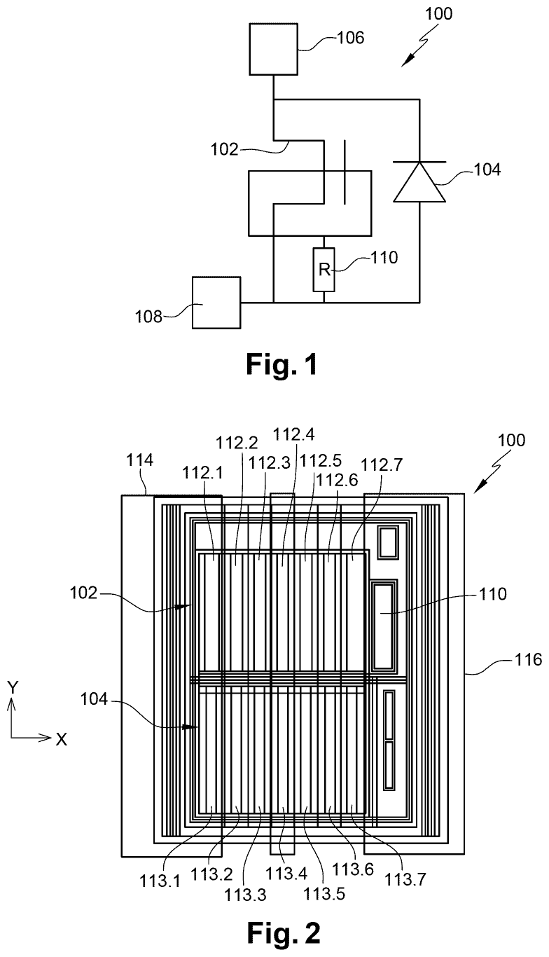

An example of embodiment of an ESD protection device 100 is described hereafter in relation with FIG. 1.

Device 100 includes at least one semiconductor electronic switch 102 corresponding to a transistor or a thyristor. In the example of FIG. 1, switch 102 is formed by, or includes, a transistor that may be of GGNMOS, or GCPMOS (Gate Coupled PMOS), or BiCMOS type (an NMOS-type transistor is shown in FIG. 1). As a variant, it is possible for switch 102 to be formed by, or to include, a triac or a bipolar transistor, or more generally any component configured to dissipate an electrostatic discharge.

According to another variant, it is possible for semiconductor electronic switch 102 to be formed by, or to include, a diode, or a plurality of diodes coupled in series when voltages greater than a turn-on threshold of a single diode (for example 0.6 V) have to be withstood.

Throughout the document, the expression “semiconductor electronic switch” designates one or a plurality of semiconductor electronic components allowing or not the flowing of a current for example according to the value of a control signal applied to this or these components and/or according to a current flow direction.

Switch 102 is coupled in parallel with a diode 104. In the example of FIG. 1, the anode of diode 104 is electrically coupled to the source of the transistor forming switch 102, and the cathode of diode 104 is electrically coupled to the drain of this transistor. According to an example of embodiment, diode 104 may be of “gated diode” type, that is, including a gate to separate the anode and the cathode of diode 104, or STI (“Silicon Trench Isolation”), that is, including an insulating trench to separate the anode and the cathode of diode 104.

The device 100 shown in FIG. 1 further includes a first connection terminal 106 having the cathode of diode 104 and a first current I/O electrode of switch 102 (this first electrode corresponding to the drain of the transistor in the example of FIG. 1) electrically coupled thereto. A power supply voltage of an integrated circuit including device 100 is for example intended to be applied to this first connection terminal 106.

The device 100 shown in FIG. 1 further includes a second connection terminal 108 having the anode of diode 104 and a second current I/O electrode of switch 102 (this second electrode corresponding to the source of the transistor in the example of FIG. 1) electrically coupled thereto. This second connection terminal 108 is for example intended to be coupled to a reference electric potential, that is, the ground, of the integrated circuit including device 100.

When semiconductor electronic switch 102 is formed by, or includes, a diode, or a plurality of diodes coupled in series, the anode of this diode (or of each of these diodes in the case of a plurality of diodes coupled in series) may be coupled to first connection terminal 106, and the cathode of this diode (or of each of these diodes in the case of a plurality of diodes coupled in series) may be coupled to second connection terminal 108.

In the example of FIG. 1, device 100 further includes a resistor 110. In the described specific configuration, a first electrode of resistor 110 is electrically coupled to the gate and to the electrode of the substrate, or “bulk” electrode, of the transistor forming switch 102, and a second electrode of resistor 110 is electrically coupled to the second current I/O electrode of switch 102, that is, the source of the transistor in the example of FIG. 1, and thus also to the anode of diode 104 and to second connection terminal 108. According to an example of embodiment, the value of resistor 110 may be in the range from 500 Ohms to 10 kOhms. Resistor 110 may enable to adjust the turn-on voltage of the parasitic bipolar transistor of the MOS transistor forming switch 102. Indeed, this parasitic bipolar transistor will precisely conduct the entire discharge for a positive ESD between terminals 106 and 108. For a negative ESD between terminals 106 and 108, the current will be drained off through diode 104.

Although they are not shown, device 100 may comprise other components coupled to switch 102 and to diode 104, such as for example a flip-flop or other resistors.

Switch 102 and diode 104 each comprise at least one finger extending substantially parallel to a first direction and which are aligned with each other along this first direction. These features are shown in FIG. 2, which shows an example of topology, or layout, of device 100.

In the example of FIG. 2, switch 102 and diode 104 each comprise a plurality of fingers. The fingers of switch 102 are designated with references 112.1-112.7, and those of diode 104 are designated with references 113.1-113.7. Each finger 112.1-112.7 of switch 102 is aligned with one of the fingers 113.1-113.7 of diode 104 along the first direction, forming together a pair of fingers. The pairs of fingers 112.1-112.7, 113.1-113.7 are aligned with respect to each other along a second direction substantially perpendicular to the first direction. In FIG. 2, the first direction is parallel to axis Y, and the second direction is parallel to axis X. In one embodiment, each finger 112.1-112.7 corresponds to a strip of semiconductor material. In one embodiment, each finger 113.1-113.7 corresponds to a strip of semiconductor material.

For switch 102, each finger 112.1-112.7 may correspond to an active portion of switch 102. More particularly, when switch 102 is formed by, or includes, a transistor, each finger 112.1-112.7 may comprise a semiconductor region having portions of the source, channel, and drain regions of the transistor formed therein, with a portion of the transistor gate extending above this portion of the channel region. The width of this portion of the gate, which corresponds to the dimension of the gate which is substantially perpendicular to the direction of alignment of the source, drain, and channel regions of the transistor (that is, the current flow direction in the active portion of the transistor), may be substantially parallel to the first direction, and the length of this portion of the gate may be substantially perpendicular to the first direction.

For diode 104, each finger 113.1-113.7 may correspond to an active portion of diode 104 including portions of the anode and cathode regions of diode 104 extending substantially parallel next to each other and substantially parallel to the first direction.

In the example of FIG. 2, resistor 110 is arranged so that it has its larger dimension substantially parallel to the first direction.

This paired configuration of fingers 112.1-112.7; 113.1-113.7 of switch 102 and of diode 104 may allow a modular design of device 100. According to this modular design, device 100 may comprise a first fixed portion (where the term “fixed” can here be understood as “always present”) including a pair of fingers of switch 102 and of diode 104. In FIG. 2, this first fixed portion is delimited by a rectangle designated by reference numeral 114 and includes the pair of fingers 112.1, 113.1. Device 100 may also comprise a second fixed portion including, in particular, the component(s) of device 100 other than the fingers of switch 102 and of diode 104, that is, resistor 110 in the described example. In FIG. 2, this second fixed portion is delimited by a rectangle designated with reference 116.

Between the two fixed portions 114, 116, one or a plurality of pairs of fingers of switch 102 and of diode 104 may be present (pairs 112.2-112.7, 113.2-113.7 in FIG. 2). The number of pairs of fingers of switch 102 and of diode 104 present between fixed portions 114, 116 is selected, on design of device 100, according to the value of the electrostatic discharge of a voltage intended to be withstood by device 100 both for electrostatic voltage discharges on the substrate (before packaging) and those on the package.

In one embodiment, a finger of the diode includes lateral sides which are parallel to the first direction and aligned with lateral sides of the finger of the semiconductor electronic switch which are also parallel to the first direction.

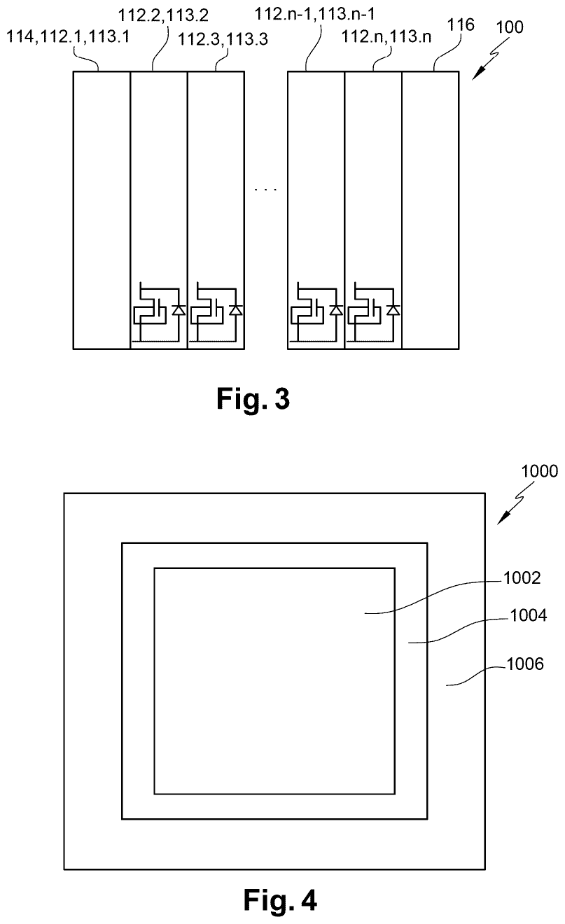

FIG. 3 shows, in the form of a functional diagram, the modular structure of device 100. In this drawing, device 100 includes the two fixed portions 114, 116 (fixed portion 114 including the first pair of fingers 112.1, 113.1 of switch 102 and of diode 104) and the possible additional n−1 pairs of fingers 112.2-112.n of switch 102 and 113.2-113.n of diode 104, interposed between fixed portions 114, 116, n being an integer number greater than or equal to 1.

For example, each pair of fingers 112.1-112.n, 113.1-113.n of switch 102 and of diode 104 may be sized to withstand, by itself, an electrostatic discharge with a voltage value at least equal to a target ESD protection value at the substrate, for example equal to approximately 100 V or 200 V HBM. Thus, even with no pair of fingers of switch 102 and of diode 104 present between fixed portions 114, 116, the pair of fingers of switch 102 and of diode 104 (designated with reference 112.1, 113.1 in FIG. 2) present in fixed portion 114 ensures that device 100 can withstand an electrostatic discharge with a voltage value equal to the target ESD protection value for the substrate. In the example of FIG. 2, considering that each of the pairs of fingers 112.1-112.7, 113.1-113.7 enables to withstand an electrostatic discharge having a voltage equal to approximately 100 V HBM, the shown device 100 is configured to withstand an electrostatic discharge having a voltage equal to approximately 700 V HBM. In a specific configuration, device 100 may comprise a number of pairs of fingers of switch 102 and of diode 104 enabling it to withstand an electrostatic discharge having a voltage value in the range from approximately 100 V HBM to 2,000 V HBM.

FIG. 4 schematically shows an integrated circuit 1000 including a plurality of ESD protection devices 100.

Integrated circuit 1000 includes a core region 1002 including for example computing circuits, memory circuits, controllers, etc. Integrated circuit 1000 also includes an I/O circuit 1004, also called “I/O ring,” arranged at the periphery of core region 1002 and including ESD protection devices 100 (not shown in FIG. 4).

Each of the ESD protection devices 100 is electrically coupled to one of the inputs/outputs of integrated circuit 1000. By forming devices 100 such that each includes at least one pair of fingers of switch 102 and of diode 104 sized to withstand an electrostatic discharge with a voltage value at least equal to the target ESD protection value for the substrate, for example equal to approximately 100 V or 200 V HBM, each of the inputs/outputs of integrated circuit 1000 is well protected from electrostatic discharges at the substrate by one of devices 100.

Integrated circuit 1000 further includes a package 1006 provided with a plurality of pins (not shown in FIG. 4), each electrically coupled to at least one of the inputs/outputs of integrated circuit 1000. Some of these pins, for example those on which the power supply voltage of integrated circuit 1000 is intended to be applied, may be electrically coupled together, forming a group of pins. The devices 100 which are electrically coupled to the pins electrically coupled together of this group may be configured, or sized, to withstand together an electrostatic discharge having a voltage value equal to a target ESD protection value for the package, for example equal to approximately 2,000 V HBM. Thus, integrated circuit 1000 it well protected at each of the pins of the package 1006 of integrated circuit 1000.

Thus, by using devices 100 within integrated circuit 1000, it is possible to decrease the occupied surface area dedicated to the ESD protection of the inputs/outputs of integrated circuit 1000 for the substrate while maintaining the ESD protection level called for the package due to the fact that it is possible to individually and easily configure, or size, each of devices 100, by selecting the number of pairs of fingers of switch 102 and of diode 104 present in each of devices 100 (modularity of devices 100). The modularity of devices 100 enables to avoid a significant development of these devices 100.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

ESD protection device (100) includes at least one semiconductor electronic switch (102) electrically coupled in parallel with a diode (104), wherein the semiconductor electronic switch (102) and the diode (104) each include at least one finger (112.1-112.7; 113.1-113.7) extending substantially parallel to a first direction, the fingers (112.1-112.7; 113.1-113.7) of the semiconductor electronic switch (102) and of the diode (104) being aligned with each other along this first direction.

The semiconductor electronic switch (102) and the diode (104) each include a plurality of fingers (112.1-112.7; 113.1-113.7), each finger (112.1-112.7) of the semiconductor electronic switch (102) being aligned with one of the fingers (113.1-113.7) of the diode (104) along the first direction, forming together a pair of fingers (112.1-112.7; 113.1-113.7), the pairs of fingers (112.1-112.7; 113.1-113.7) being aligned with one another along a second direction substantially perpendicular to the first direction.

ESD protection device (100) includes at least one resistor (110) having a larger dimension substantially parallel to the first direction.

The semiconductor electronic switch (102) include a GGNMOS- or GCPMOS- or BiCMOS-type transistor, or comprises a thyristor.

ESD protection device (100) further includes two connection terminals (106, 108) having electrodes of the semiconductor electronic switch (102) and of the diode (104) coupled thereto.

The semiconductor electronic switch (102) and the diode (104), or each pair of fingers (112.1-112.7; 113.1-113.7) of the semiconductor electronic switch (102) and of the diode (104) when the semiconductor electronic switch (102) and the diode (104) each include a plurality of fingers (112.1-112.7; 113.1-113.7), are configured to withstand an electrostatic discharge voltage having a value equal to a target ESD protection value for the substrate.

Integrated circuit (1000) including a plurality of inputs/outputs, each electrically coupled to at least one ESD protection device (100).

The ESD protection devices (100) form part of an I/O circuit (1004) arranged at the periphery of a core region (1002) of the integrated circuit (1000).

Integrated circuit (1000) further includes a package (1006) provided with a plurality of pins, each electrically coupled to at least one of the inputs/outputs, at least one group of pins being electrically coupled together, the ESD protection device (100) coupled to the group of pins or to each of the groups of pins being configured to withstand together an electrostatic discharge voltage having a value equal to a target ESD protection value for the package.

At least one of the pins of the package is electrically coupled to none of the other pins, the ESD protection device (100) coupled to said at least one of the pins being configured to withstand alone an electrostatic discharge voltage having a value equal to the target ESD protection value for the package.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An electrostatic discharge (ESD) protection device comprising:
a diode including at least one first finger; and
at least one semiconductor electronic switch electrically coupled in parallel with the diode and including at least one second finger, wherein the at least one first finger and the at least one second finger extend substantially parallel to a first direction and are aligned with each other along the first direction.

2. The ESD protection device according to claim 1, wherein the semiconductor electronic switch includes a plurality of second fingers and the diode includes a plurality of first fingers, each second finger of the semiconductor electronic switch being aligned with one of the first fingers of the diode along the first direction, forming together a pair of fingers, the pairs of fingers being aligned with one another along a second direction substantially perpendicular to the first direction.

3. The ESD protection device according to claim 2, comprising at least one resistor having a larger dimension substantially parallel to the first direction.

4. The ESD protection device according to claim 1, wherein the semiconductor electronic switch includes a GGNMOS- or GCPMOS- or BiCMOS-type transistor, or a thyristor.

5. The ESD protection device according to claim 1, further comprising two connection terminals coupled to electrodes of the semiconductor electronic switch and of the diode.

6. The ESD protection device according to claim 1, wherein the semiconductor electronic switch and the diode are configured to withstand an electrostatic discharge voltage having a value equal to a target ESD protection value for the substrate.

7. The ESD protection device according to claim 1, wherein the at least one first finger of the diode includes lateral sides which are parallel to the first direction and aligned with lateral sides of the at least one second finger of the semiconductor electronic switch, wherein the lateral sides of the at least one second finger are parallel to the first direction.

8. An integrated circuit comprising:
an electrostatic discharge (ESD) protection device including:
a plurality of diodes each including a first finger extending in a first direction; and
a plurality of switches each including a second finger extending in the first direction and aligned in the first direction with a respective first finger; and
a plurality of input/output (I/O) terminals electrically coupled the ESD protection device.

9. The integrated circuit according to claim 8, further comprising:
a core region; and
an I/O circuit arranged at the periphery of the core region of the integrated circuit and including the ESD protection device.

10. The integrated circuit according to claim 8, further comprising a package including a plurality of pins, each electrically coupled to at least one of the I/O terminals, at least one group of pins being electrically coupled together, the ESD protection device coupled to the group of pins or to each of the groups of pins being configured to withstand together an electrostatic discharge voltage having a value equal to a target ESD protection value for the package.

11. The integrated circuit according to claim 10, wherein at least one of the pins of the package is electrically coupled to none of the other pins, the ESD protection device coupled to said at least one of the pins being configured to withstand alone an electrostatic discharge voltage having a value equal to the target ESD protection value for the package.

12. The integrated circuit of claim 10, wherein the core region includes one or more of a memory circuit and a controller.

13. The integrated circuit of claim 8, wherein each switch and respective diode are electrically coupled in parallel.

14. The integrated circuit of claim 8, wherein the ESD protection device includes a resistor coupled to a control terminal of at least one of the switches.

15. The integrated circuit of claim 8, wherein the switch includes a GGNMOS- or GCPMOS- or BiCMOS-type transistor, or a thyristor.

16. An integrated circuit, comprising an electrostatic discharge (ESD) protection device, the ESD protection device including:
a plurality of pairs of fingers, each pair of fingers including a first finger and a second finger each extending in a first direction and aligned with each other along the first direction;
a plurality of diodes, each diode including a respective first finger; and
a plurality of switches, each switch including a respective second finger.

17. The integrated circuit of claim 16, wherein each first finger is first strip of semiconductor material, wherein each second finger is a second strip of semiconductor material.

18. The integrated circuit of claim 16, wherein each pair of fingers corresponds to one of the diodes and one of the switches electrically coupled in parallel.

19. The integrated circuit of claim 16, wherein the ESD protection device includes a resistor extending in the first direction and being wider in a second direction than the first and second fingers.

20. The integrated circuit of claim 16, wherein each switch includes a transistor having a gate terminal and a body terminal coupled together.
